(19) United States
(12) Patent Application Publication
(10) Pub. No.: US 2009/0195421 A1
(43) Pub. Date: Aug. 6, 2009

(54) METHOD AND APPARATUS FOR CONTROLLING DIGITAL SUM VALUE AND RECORDING MEDIUM FOR EXECUTING THE METHOD

(75) Inventors: Jin-Han Kim, Suwon-si (KR); Sung-hee Hwang, Suwon-si (KR)

Correspondence Address: STEIN MCEWEN, LLP, 1400 EYE STREET, NW, SUITE 300, WASHINGTON, DC, 20005, US

(73) Assignee: Samsung Electronics Co., Ltd., Suwon-si (KR)

(21) Appl. No.: 12/184,565

(22) Filed: Aug. 1, 2008

(30) Foreign Application Priority Data
Feb. 4, 2008 (KR) 2008-11060

(51) Int. Cl. H03M 7/00

(52) U.S. Cl. 341/59

(57) ABSTRACT

A method of controlling a Digital Sum Value (DSV), including generating a plurality of DSV control bit patterns indicating predetermined information represented by at least one bit; and inserting any one of the generated DSV control bit patterns at a predetermined location of a modulated codeword. The plurality of the DSV control bit patterns indicate predetermined information represented by at least one bit so that the DSV control bit patterns control the DSV and can be used as predetermined information, instead of being discarded after the demodulation is completed.

### CROSS-REFERENCE TO RELATED APPLICATION

This application claims the benefit of Korean Patent Application No. 2008-11060, filed in the Korean Intellectual Property Office on Feb. 4, 2008, the disclosure of which is incorporated herein by reference.

### BACKGROUND OF THE INVENTION

1. Field of the Invention

Aspects of the present invention relate to a method and apparatus to control a Digital Sum Value (DSV) and a recording medium to execute the method, and more particularly, to a method and apparatus to control a DSV and to store an information bit by generating a plurality of DSV control bit patterns during data modulation and inserting the DSV control bit patterns into a codeword, wherein the DSV control bit patterns indicate predetermined information represented by bits during data modulation, and a recording medium for executing the method.

2. Description of the Related Art

Information recorded as marks and spaces on an optical information storage medium is modulated to data bits by Run Length Limited (RLL) coding. Then, the modulated information is converted into Non-Return-to-Zero Inverted (NRZI) data and stored. The NRZI data is in a binary form. Due to such form including consecutive 1's and 0's, a Digital Sum Value (DSV) exists.

The DSV is a value summed by counting data segments ‘0’ as ‘−1’ and ‘1’ as ‘+1’ in a pattern obtained after converting a data segment level each time ‘1’ appears in a codeword stream. The DSV affects the quality of write/reproduction signals. In general, when the DSV approaches 0, the quality of the write/reproduction signals increases. When the NRZI data includes a direct current (DC) component, various error signals (such as a tracking error generated during servo control by a disk drive) may change or jitter may easily occur. Accordingly, the modulated code should not include a DC component. The DSV indicates that a DC component is included in a code string, and suppressing the size of a DC component included within a code string is done by decreasing an absolute value of the DSV through DSV control.

DSV control methods for suppressing a DC component can be classified into two methods. In the first method, a DSV control code capable of controlling the DSV is inserted in a codeword. In the second method, a predetermined DSV control bit is inserted during a predetermined period. In an Eight Fourteen Modulation plus (EFM+) code, DSV is controlled using a separate code table, and in an Eight Fourteen Modulation (EFM) or an RLL (1, 7) Parity Preserving (PP) code, DSV is controlled by inserting a DSV control bit.

A DSV control method including inserting a DSV control bit in a data row before modulation, calculating the DSV of a channel bit row encoded after modulation according to an RLL (1, 7) code table, and selecting the channel bit row which suppresses a DC component is disclosed in PCT WO99/063671 A1, “Apparatus and Method for Modulation/Demodulation with Consecutive Minimum Run Length Limitation.” However, the DSV control disclosed in this publication is not applied to a modulation code generated according to the RLL (1, 7) code table. In addition, the DSV control bit inserted to control the DSV before modulation is a redundancy bit which does not have specific information, and thus cannot be used in various other ways while demodulating the DSV control bit.

### SUMMARY OF THE INVENTION

Aspects of the present invention provide a method and apparatus for controlling a Digital Sum Value (DSV) and storing information bit by generating DSV control bit patterns during data modulation and inserting the DSV control bit patterns into a codeword, and a recording medium for executing the method.

According to an aspect of the present invention, a method of controlling a Digital Sum Value (DSV) is provided. The method includes generating a plurality of DSV control bit patterns indicating predetermined information represented by at least one bit; inserting any one of the generated DSV control bit patterns at a predetermined location of a modulated codeword; and recording the modulated codeword having the inserted DSV control bit pattern onto a computer-readable medium.

According to another aspect of the present invention, the method further includes modulating an input dataword to a codeword according to a predetermined modulation code table.

According to another aspect of the present invention, the plurality of the DSV control bit patterns are generated to satisfy a RLL (d, k) rule, wherein d and k are respectively the minimum length and the maximum length of consecutive O's in which a codeword to which the one DSV control bit pattern is inserted.

According to another aspect of the present invention, d is 1 and k is 7.

According to another aspect of the present invention, the plurality of the DSV control bit patterns have parities opposite to each other.

According to another aspect of the present invention, the plurality of the DSV control bit patterns have opposite Codeword Sum Values (CSVs) having opposite signs, the CSV indicating the DSV of one codeword.

According to another aspect of the present invention, the plurality of the DSV control bit patterns have parities opposite to each other and CSVs having opposite signs.

According to another aspect of the present invention, the inserting of any one of the generated DSV control bit patterns at a predetermined location of the modulated codeword may include inserting the DSV control bit pattern at any one of a location between the most significant bit (MSB) and the least significant bit (LSB) of the modulated codeword, a location after the LSB of the codeword, and a location before the MSB of codeword.

According to another aspect of the present invention, a method of controlling a Digital Sum Value (DSV) is provided. The method includes separating a plurality of the DSV control bit patterns inserted into a modulated codeword and a codeword, wherein the plurality of the DSV control bit patterns indicates predetermined information represented by at least one bit; converting the separated DSV control bit patterns into at least one bit which represents the predetermined information; and reproducing data contained in the codeword based on the predetermined information.

According to another aspect of the present invention, the method further includes demodulating the separated codeword to a dataword according to a predetermined demodulation table.

According to another aspect of the present invention, the predetermined information includes any one of address information to rapidly and randomly access data and determine a data recorded location; padding information indicating that unavailable data is contained while recording data; information indicating whether data type is real-time data; information indicating whether data is provided by a host; disk management information; information indicating data generated by a drive itself; copy protection information for encryption; and information indicating an encryption key.

According to another aspect of the present invention, an apparatus to control a Digital Sum Value (DSV) is provided. The apparatus includes a DSV control bit pattern generating unit to generate a plurality of the DSV control bit patterns indicating predetermined information represented by at least one bit; and a DSV control bit pattern inserting unit to insert any one of the generated DSV control bit patterns into a modulated codeword.

According to another aspect of the present invention, an apparatus to control a Digital Sum Value (DSV) is provided. The apparatus includes a DSV control bit pattern separating unit to separate a plurality of DSV control bit patterns inserted into a modulated codeword and a codeword, wherein the plurality of DSV control bit patterns indicates predetermined information represented by at least one bit; and an information bit converting unit to convert the separated DSV control bit patterns into at least one bit that represents the predetermined information.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a flowchart of a process of controlling a Digital Sum Value (DSV), according to an embodiment of the present invention;

FIG. 2 illustrates a modulation code table;

FIGS. 3A through 3C illustrate DSV control bit patterns including 1-bit information and opposite parity, according to an embodiment of the present invention;

FIG. 4A through 4C illustrate DSV control bit patterns including 1-bit information and an opposite Codeword Sum Value (CSV), according to an embodiment of the present invention;

FIGS. 5A through 5C illustrate DSV control bit patterns including 1-bit information, and opposite parity and CSV, according to an embodiment of the present invention;

FIGS. 6A through 6C illustrate DSV control bit patterns including 1-bit information and opposite parity, according to another embodiment of the present invention;

FIGS. 7A through 7C illustrate DSV control bit patterns including 1-bit information and opposite CSV, according to another embodiment of the present invention;

FIGS. 8A through 8C illustrate DSV control bit patterns including 2-bit information and opposite CSV, according to an embodiment of the present invention;

FIGS. 9A through 9C illustrate DSV control bit patterns including 2-bit information and opposite CSV, according to an embodiment of the present invention;

FIGS. 10A through 10C illustrate DSV control bit patterns including 2-bit information and opposite parity and CSV, according to an embodiment of the present invention;

FIGS. 11 through 14 are graphs illustrating simulations of DSV control performances by inserting DSV control bit patterns indicating 1-bit information to modulated codeword, according to an embodiment of the present invention;

FIG. 15 is a flowchart illustrating a method of controlling a DSV, according to another embodiment of the present invention;

FIG. 16 is a block diagram of an apparatus for controlling a DSV, according to an embodiment of the present invention; and

FIG. 17 is a block diagram of an apparatus for controlling a DSV, according to another embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

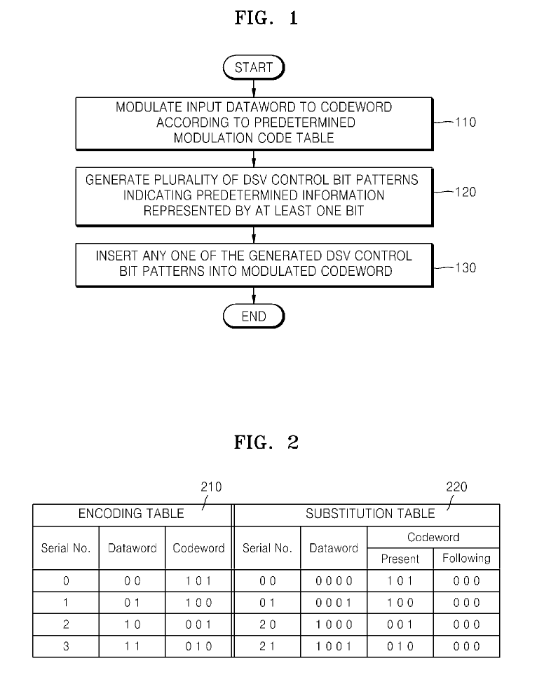

FIG. 1 is a flowchart of a process of controlling a Digital Sum Value (DSV), according to an embodiment of the present invention. An input dataword is modulated to a codeword according to a predetermined modulation code table in operation 110. In a digital recording system, a modulation code is used to reduce channel distortion such as intersymbol interference and to prevent occurrence of an error due to a specific data pattern.

FIG. 2 shows a modulation code table. The modulation code table is used to convert a dataword into a codeword. The modulation code table of FIG. 2 is a Jacoby code table. The Jacoby code table is disclosed in U.S. Pat. No. 4,337,458. The Jacoby code table includes an encoding table 210 and a substitution table 220. In general, the Jacoby code converts 2-bit data into 3-bit code using the encoding table 210 and converts four datawords ‘0000’, ‘0001’, ‘1000,’ and ‘1001’ into a 6-bit codeword using the substitution table 220 in order to conform an RLL (1, 7) rule.

RLL stands for Run Length Limited. The RLL (1, 7) rule denotes that the minimum number and the maximum number of 0's allowed to be placed between 1's that are adjacent to each other in a codeword are respectively one and seven. According to the Jacoby code table, when an input dataword is ‘00000011’, the codeword is changed to ‘101000101010.’ Firstly, 4-bits of a dataword is searched for to determine whether a dataword corresponding to a 4-bit dataword exists in the substitution table 220. If a dataword corresponding to 4-bit dataword exists in the substitution table 220, the dataword is converted into a codeword according to the substitution table 220. Thus, a dataword ‘0000’ is converted into ‘101000.’ When a 2-bit dataword is converted into a codeword according to the encoding table 210, the RLL (1, 7) rule cannot be satisfied. In the case of ‘0000,’ a dataword ‘00’ exists in the encoding table 210 so that the dataword ‘00’ is converted into a codeword ‘101’ and the next dataword ‘00’ is also converted into the codeword ‘101.’ In this case, the codeword becomes ‘101101.’ However, this case does not satisfy the RLL (1, 7) rule in which the minimum number of consecutive 0 should be more than 0. Accordingly, after determining whether a 4-bit dataword exists in the substitution table 220, if the corresponding codeword does not exist, a dataword is converted according to the encoding table 210. A 4-bit dataword placed after ‘0000’ is ‘0011.’ A dataword ‘0011’ does not exist in the substitution table 220. Thus, ‘0011’ should be converted according to the encoding table 210. In a dataword ‘0011,’ dataword ‘00’ and ‘11’ are respectively converted into a codeword ‘101’ and ‘010.’ Therefore, a dataword ‘00000011’ is converted into a codeword ‘101000101010’ and the codeword satisfies the RLL (1, 7) rule. The Jacoby code table that is a modulation code table in the present invention is only an example and can have various forms. However, the modulation code table should satisfy the RLL (1, 7) rule.

In operation 120, a plurality of DSV control bit patterns indicating predetermined information represented by at least one bit is generated. The predetermined information is received from the outside. 1-bit information is represented by ‘0’ or ‘1’, and 2-bit information is represented by ‘00’, ‘01’, ‘10,’ or ‘11.’ The at least one bit is referred to as an information bit.

Examples of the predetermined information include: address information to rapidly and randomly access data and find out data recorded location; padding information indicating that unavailable data is contained while recording data; information indicating whether data type is real-time data; information indicating whether data is provided by a host; disk management information; information indicating data generated by a drive itself (such as a hard drive) that is similar to a disk; copy protection information for encryption; and information indicating an encryption key. However, the predetermined information is not limited to these examples, and may be any type of predetermined information.

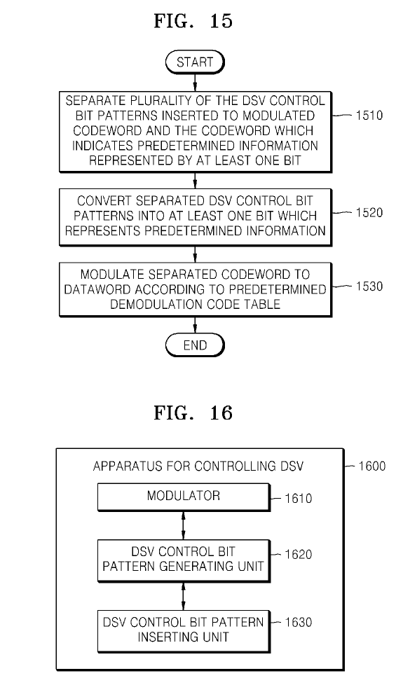

The DSV control bit patterns indicate the predetermined information represented by at least one bit. For example, when information bit indicating 1-bit information is ‘0’ or ‘1,’ the DSV control bit pattern indicating ‘0’ is generated or the DSV control bit pattern indicating ‘1’ is generated. When the DSV control bit pattern indicating ‘0’ is ‘001010,’ only the DSV control bit pattern is inserted and then is separated from a codeword. Then, the DSV control bit pattern in which the separated codeword is to be demodulated is converted into information bit ‘0.’ This will be described in more detail with reference to FIG. 15. Information indicating that the DSV control bit pattern ‘001010’ represents information bit ‘0’ may be stored in a predetermined circuit.

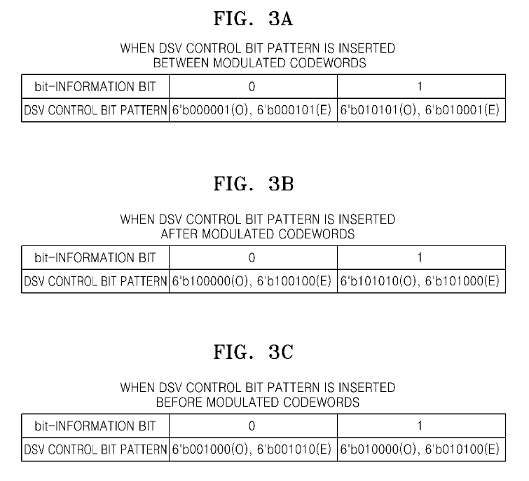

When the DSV control bit patterns are inserted into a modulated codeword, the DSV control bit patterns are generated to satisfy the RLL (1, 7) rule. In addition, the DSV control bit patterns are generated to have a parity opposite to data parity, each data representing an information bit, or to have a Codeword Sum Value (CSV) having an opposite sign. The CSV is a DSV of a codeword. This will be described with reference to FIGS. 3-10.

In operation 130, any one of the generated DSV control bit patterns is inserted into the modulated codeword. The DSV control bit pattern may be inserted into a codeword according to a predetermined cycle or at a predetermined location of a codeword. The codeword including the DSV control bit pattern that suppresses a Direct Current (DC) component is selected from among modulated codewords including previously inserted DSV control bit patterns so as to suppress the DC component. Since the DSV control bit pattern is inserted between modulated codewords, the RLL rule, the basic rule of modulation code, should be satisfied by the DSV control bit pattern. The RLL rule should be satisfied in consideration of the modulation code located before and after the location where the DSV control bit pattern is inserted (for example, one or two modulation codes).

FIGS. 3A through 3C show DSV control bit patterns including 1-bit information and opposite parity, according to an embodiment of the present invention. Referring to FIG. 3A, the DSV control bit pattern is inserted between the present code bit and the following code bit in the substitution table 220 of FIG. 2. The DSV control bit pattern is inserted between the Most Significant Bit (MSB) and the Least Significant Bit (LSB) of the modulated codeword. If the information bit is ‘0,’ the DSV control bit patterns ‘000001’ and ‘000101’ are generated. In the control bit pattern ‘000001,’ there exists an odd number of 1's and thus parity is odd. In the control bit pattern ‘000101,’ there exists an even number of 1's and thus the parity is even. One DSV control bit pattern is determined from among the two DSV control patterns and is inserted into the codeword. In FIG. 3A, if the information bit is ‘1,’ one of ‘010101’ and ‘010001’ is inserted. In FIG. 3A, ‘6′b’ denotes 6-bit, (O) denotes ‘odd,’ and (E) denotes ‘even.’

Referring to FIG. 3B, the DSV control bit pattern is inserted after the following code bit in the substitution table 220. The DSV control bit pattern is inserted after the LSB of the codeword in the substitution table 220. If the information bit is ‘0,’ the DSV control bit patterns ‘100000’ and ‘100100’ are generated. In the control bit pattern ‘100000,’ there exists an odd number of 1's and thus parity is odd. In the control bit pattern ‘000101,’ there exists an even number of 1's and thus the parity is even. One DSV control bit pattern is determined from among the two DSV control patterns and is inserted into the codeword. In FIG. 3B, if the information bit is ‘1,’ one of ‘101010’ and ‘101000’ is inserted.

Referring to FIG. 3C, the DSV control bit pattern is inserted after a codeword in the encoding table 210 of FIG. 2. The DSV control bit pattern is inserted before the MSB of the codeword in the substitution table 220. If the information bit is ‘0,’ the DSV control patterns ‘001000’ and ‘001010’ are generated. In the DSV control pattern ‘001000,’ there exists an odd number of 1's and thus the parity is odd. In the DSV control pattern ‘001010,’ there exists an even number of 1's and thus the parity is even. One DSV control bit pattern is determined from among the two DSV control patterns and is inserted into the codeword. In FIG. 3C, if the information bit is ‘1,’ one of ‘010000’ and ‘010100’ is inserted.

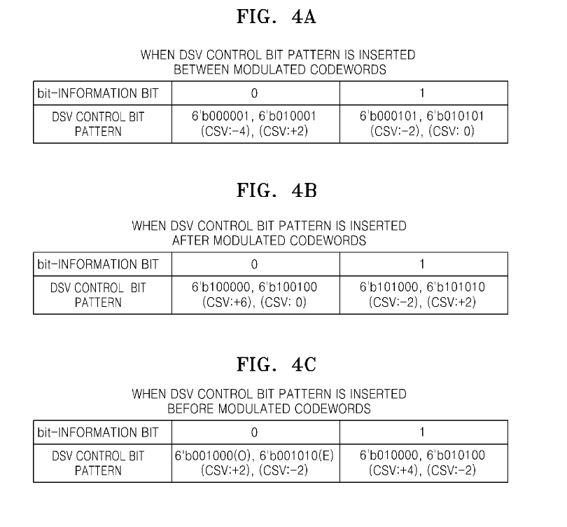

FIG. 4A through 4C show DSV control bit patterns including 1-bit information and an opposite CSV, according to an embodiment of the present invention. Referring to FIG. 4A, the DSV control bit pattern is inserted into the present code bit and the following code bit in the substitution table 220. If the information bit is ‘0,’ the DSV control bit patterns ‘000001’ and ‘010001’ are generated. In ‘000001,’ the CSV is −4 and in ‘010001,’ the CSV is +2. Thus, the CSVs are opposite to each other. In FIG. 4A, if the information bit is ‘1,’ one of ‘000101’ and ‘010101’ is inserted. The CSV of ‘000101’ is 2 and the CSV of ‘010101’ is 0. When the CSV is ‘0,’ all CSVs are determined to have opposite values. In FIG. 4B, the DSV control bit pattern is inserted after the following code bit in the substitution table 220 of FIG. 2. In FIG. 4C, the DSV control bit pattern is inserted before the MSB of the codeword in the substitution table 220 of FIG. 2.

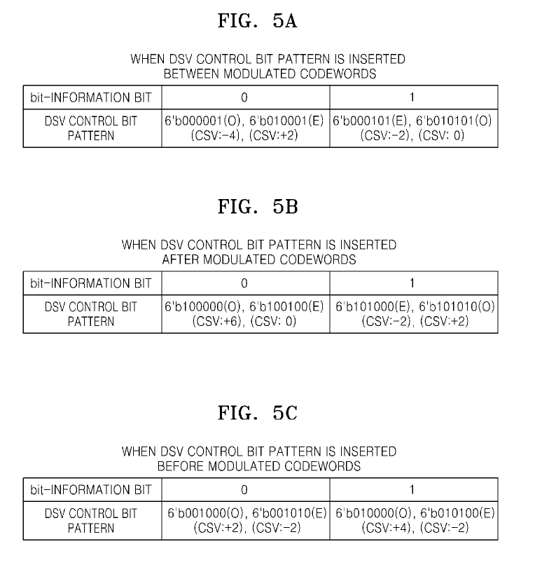

FIGS. 5A through 5C show DSV control bit patterns including 1-bit information, and opposite parity and the CSV, according to an embodiment of the present invention. Referring to FIG. 5A, the DSV control bit pattern is inserted into the present code bit and the following code bit in the substitution table 220 of FIG. 2. If the information bit is ‘0,’ the DSV control bit patterns ‘000001’ and ‘010001’ are generated. In the control bit pattern ‘000001,’ parity is odd and the CSV is −4. In the control bit pattern ‘010001,’ parity is even and the CSV is +2. Thus, parity and the CSV are contrary to each other. In FIG. 5A, if the information bit is ‘1,’ one of ‘000101’ and ‘010101’ is inserted. In the control bit pattern ‘000101,’ parity is odd and the CSV is −2. In the control bit pattern ‘010101,’ parity is even and the CSV is 0. When the CSV is ‘0,’ all CSVs are determined to have opposite values. In FIG. 5B, the DSV control bit pattern is inserted after the following code bit in the substitution table 220 of FIG. 2. In FIG. 5C, the DSV control bit pattern is inserted before the MSB of the codeword in the substitution table 220 of FIG. 2.

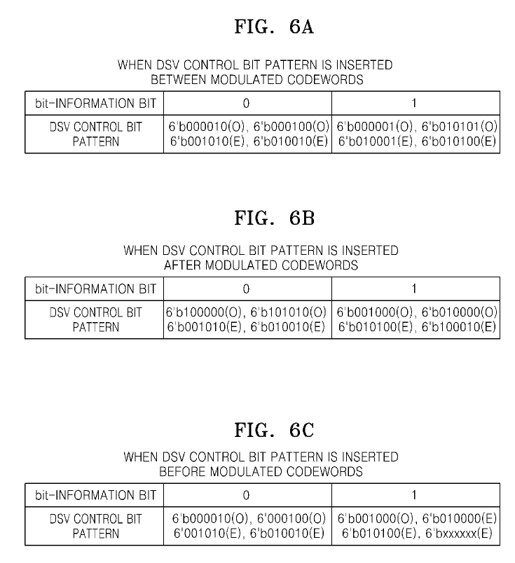

FIGS. 6A through 6C show DSV control bit patterns including 1-bit information and having opposite parities, according to another embodiment of the present invention. Unlike FIGS. 3A through 3C, FIGS. 6A through 6C show that 2 pairs of the DSV control bit patterns are arranged. Referring to FIG. 6A, the DSV control bit pattern is inserted into the present code bit and the following code bit in the substitution table 220 of FIG. 2. If the information bit is ‘0,’ the DSV control bit patterns ‘000010’, ‘000100’, ‘001010,’ and ‘010010’ are generated. In the control bit patterns ‘000010’ and ‘000100,’ there exists an odd number of 1's and thus parity is odd. In the control bit patterns ‘001010’ and ‘010010,’ there exists an even number of ‘1’ and thus parity is even. One of those four DSV control bit patterns is determined and is inserted into the codeword. In FIG. 6A, if the information bit is ‘1,’ one of ‘000001’, ‘010101’, ‘010001’, and ‘010100’ is inserted. In FIG. 6B, the DSV control bit pattern is inserted after the following code bit in the substitution table 220 of FIG. 2. In FIG. 6C, the DSV control bit pattern is inserted before the MSB of the codeword in the substitution table 220 of FIG. 2.

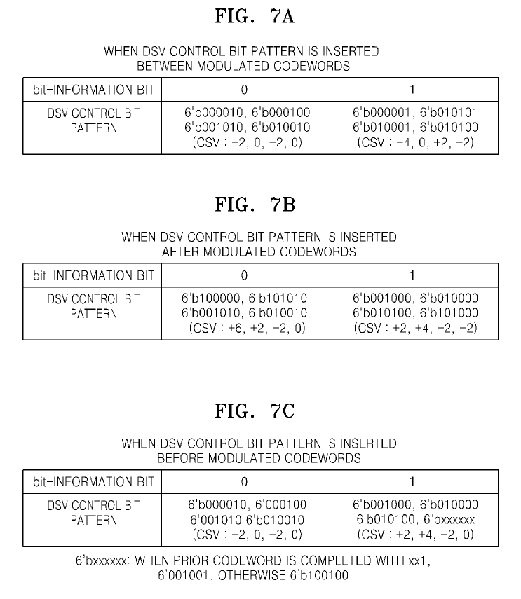

FIGS. 7A through 7C show DSV control bit patterns including 1-bit information and opposite CSV, according to another embodiment of the present invention. Unlike FIGS. 4A through 4C, FIGS. 7A through 7C show that 2 pairs of the DSV control patters are arranged. Referring to FIG. 7A, the DSV control bit pattern is inserted into the present code bit and the following code bit in the substitution table 220 of FIG. 2. In FIG. 7B, the DSV control bit pattern is inserted after the following code bit in the substitution table 220 of FIG. 2. In FIG. 7C, the DSV control bit pattern is inserted before the MSB of codeword in the substitution table 220 of FIG. 2. In the case of ‘xxxxxx’ in FIG. 7C, if the LSB of the prior codeword is ‘1’ and ‘0,’ the control bit patterns ‘001001’ and ‘100100’ are respectively generated.

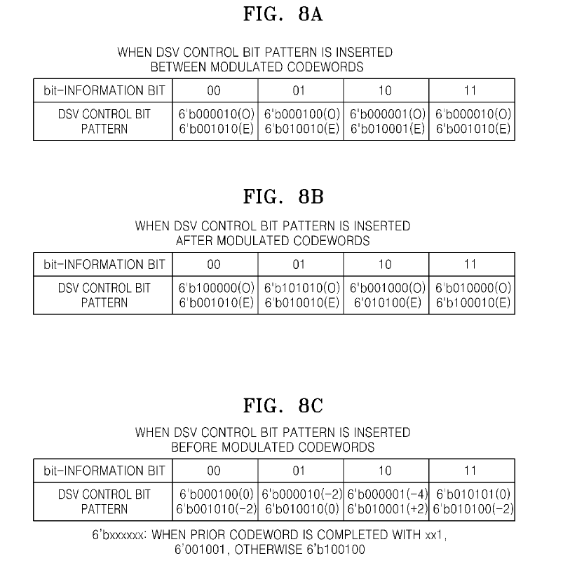

FIGS. 8A through 8C show DSV control bit patterns including 2-bit information and having opposite CSVs, according to an embodiment of the present invention. According to FIGS. 8A through 8C, the DSV control bit patterns are generated with respect to each data for ‘00, 01, 10, and 11’ indicating the information bit, in order to include 2-bit information.

Referring to FIG. 8A, the DSV control bit pattern is inserted into the present code bit and following code bit in the substitution table 220 of FIG. 2. If the information bit is ‘00,’ the DSV control bit patterns ‘000010’ and ‘001010’ are generated. In the control bit pattern ‘000010,’ there exists an odd number of 1's, and thus parity is odd. In the control bit pattern ‘001010,’ there exists an even number of 1's, and thus parity is even. One of these two DSV control bit patterns is determined and is inserted into the codeword. If the information bit is ‘01,’ one of ‘000100’ and ‘010010’ is inserted, If the information bit is ‘10,’ one of ‘000001’ and ‘010001’ is inserted. If the information bit is ‘11,’ one of ‘010101’ and ‘010100’ is inserted. In FIG. 8B, the SV control bit pattern is inserted after the following code bit in the substitution table 220 of FIG. 2. In FIG. 8C, the SV control bit pattern is inserted before the MSB of the codeword in the substitution table 220 of FIG. 2.

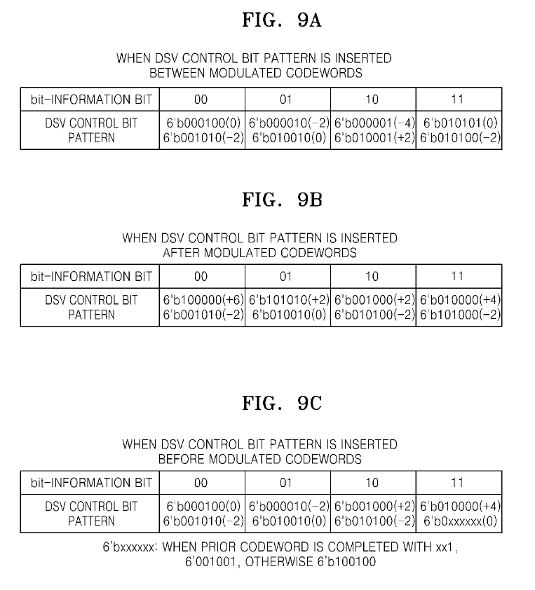

FIGS. 9A through 9C show DSV control bit patterns including 2-bit information and having opposite CSVs, according to an embodiment of the present invention. In FIG. 9A, the DSV control bit pattern is inserted into the present code bit and the following code bit in the substitution table 220 of FIG. 2. In FIG. 9B, the DSV control bit pattern is inserted after the following code bit in the substitution table 220 of FIG. 2. In FIG. 9C, the DSV control bit pattern is inserted before the MSB of the codeword in the substitution table 220 of FIG. 2.

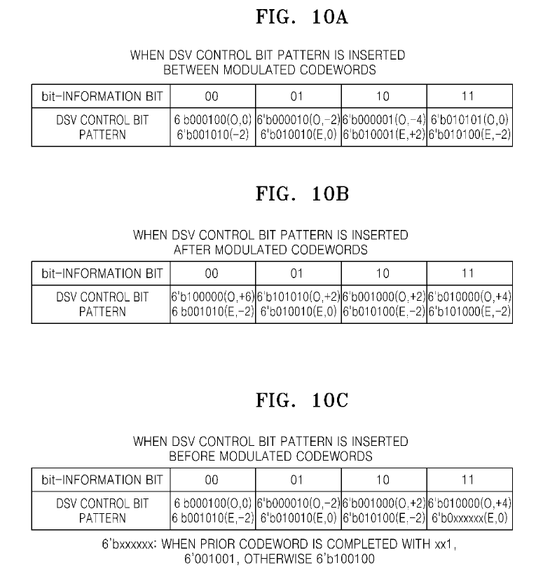

FIGS. 10A through 10C show DSV control bit patterns including 2-bit information and opposite parities and CSVs, according to an embodiment of the present invention. In FIG. 10A, the DSV control bit pattern is inserted into the present code bit and the following code bit in the substitution table 220 of FIG. 2. In FIG. 10B, the DSV control bit pattern is inserted after the following code bit in the substitution table 220 of FIG. 2. In FIG. 10C, the DSV control bit pattern is inserted before the MSB of codeword in the substitution table 220 of FIG. 2.

Bit values of the inserted DSV control bit patterns in FIGS. 3A through FIG. 10C are only examples. The bit values may vary according to a type of the modulation code table. However, although the dataword may be modulated according to any code table, the RLL (d, k) rule should be satisfied. According to some aspects of the present invention, d and k may be respectively 1 and 7. In addition, the locations where the DSV control bit patterns are inserted are only examples. The DSV control bit patterns may be inserted using previously set methods according to a predetermined location. In this case too, the RLL (d, k) rule should also be satisfied.

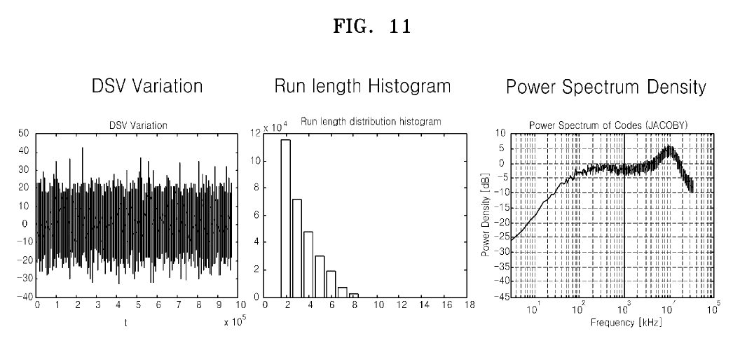

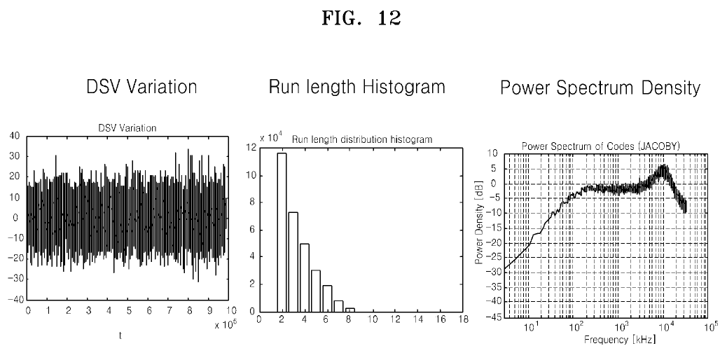

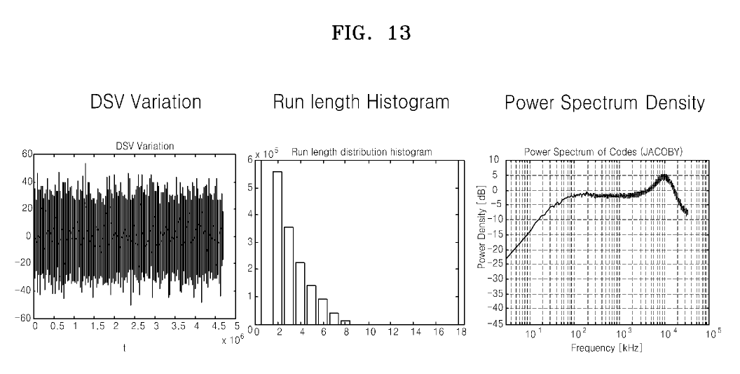

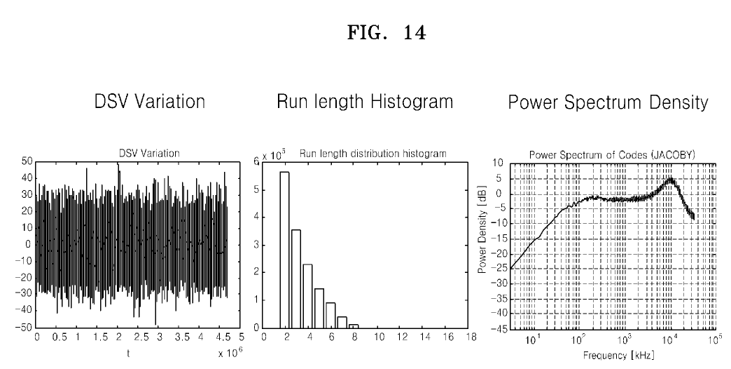

FIGS. 11 through 14 are graphs of simulations of DSV control performances by inserting the DSV control bit patterns indicating 1-bit information into a modulated codeword, according to an embodiment of the present invention. The graphs are shown in terms of DSV variation, run length histogram, and power spectrum density. In FIGS. 11 and 12, the DSV control bit patterns having opposite parities are inserted. In FIG. 11, the DSV control bit pattern is inserted in a code 126-bit interval and an add rate is 4.55%. In FIG. 12, the DSV control bit pattern is inserted in a code 90-bit interval and an add rate is 6.25%. In FIGS. 13 and 14, 2 pairs of the DSV control bit patterns having opposite parities are arranged. In FIG. 13, the DSV control bit pattern is inserted in a code 270-bit interval and an add rate is 2.17%. In FIG. 12, the DSV control bit pattern is inserted in a code 210-bit interval and an add rate is 2.78%. According to FIGS. 11 through 14, as shown in power spectrum density, power density linearly increases at a frequency between 0 and 100 [kHz]. Such a frequency band is a server control error signal band. When the DSV control bit patterns are added, the power density for a low frequency component such as a DC component is suppressed in the frequency band so that a server control error signal is not affected. The DSV control bits are redundancy bits and thus may have fewer bits as possible when considering code efficiency.

FIG. 15 is a flowchart of a method of controlling a DSV, according to another embodiment of the present invention. Referring to FIG. 15, a plurality of the DSV control bit patterns inserted into a modulated codeword and a codeword which indicates predetermined information represented by at least one bit is separated in operation 1510.

In operation 1520, the separated DSV control bit patterns are converted into at least one bit which represents predetermined information. When the DSV control bit patterns are generated, the DSV control bit patterns are converted into a previously set information bit. For example, referring to FIG. 3, when the separated DSV control bit patterns correspond to at least one of ‘000001’, ‘000101’, ‘100000’, ‘100100’, ‘001000,’ and ‘001010,’ the separated DSV control bit patterns are decoded to information bit ‘0.’ When the separated DSV control bit patterns correspond to at least one of ‘010101’, ‘010001’, ‘101010’, ‘101000’, ‘010000,’ and ‘010100,’ the separated DSV control bit patterns are decoded to information bit ‘1.’

In operation 1530, the separated codeword is demodulated to a dataword according to a predetermined demodulation code table. Demodulation progresses in the modulation reverse order in which a dataword is modulated to codeword.

FIG. 16 shows an apparatus 1600 to control the DSV, according to an embodiment of the present invention. The apparatus 1600 includes a modulator 1610, a DSV control bit pattern generating unit 1620, and a DSV control bit pattern inserting unit 1630. According to other aspects of the present invention, the apparatus 1600 may include additional and/or different units. Similarly, the functionality of two or more of the above units may be integrated into a single component.

The modulator 1610 modulates a dataword input through a communication unit (not shown) to a codeword according to a predetermined modulation code table. While modulating, the RLL rule should be satisfied.

The DSV control bit pattern generating unit 1620 generates a plurality of the DSV control bit patterns input through the communication unit (not shown) which indicate predetermined information represented by at least one bit. One-bit information is represented by ‘0’ and ‘1’ and 2-bit information is represented by ‘00’, ‘01’, ‘10,’ and ‘11.’ Examples of the predetermined information include address information to rapidly and randomly access data and determine a data recorded location; padding information indicating that unavailable data is contained while recording data; information indicating whether a data type is real-time data; information indicating whether data is provided by a host; disk management information; information indicating data generated by a drive itself that is similar to a disk (such as a hard drive); copy protection information for encryption; and information indicating an encryption key. The predetermined information is not limited to these examples, however, and may be any type of predetermined information.

The DSV control bit patterns indicate the predetermined information represented by at least one bit. For example, if an information bit indicating 1-bit information is ‘0’ and ‘1,’ the DSV control bit pattern generating unit 1620 generates the DSV control bit pattern indicating ‘0’ and the DSV control bit pattern indicating ‘1.’ When the DSV control bit pattern is inserted to the modulated codeword, the DSV control bit patterns are generated to satisfy the RLL (1, 7) rule. In addition, the DSV control bit pattern generating unit 1620 generates the DSV control bit patterns to have a parity opposite to the data, each data representing information bit, or to have a CSV having an opposite sign.

The DSV control bit pattern inserting unit 1630 inserts any one of the DSV control bit patterns generated in the DSV control bit pattern generating unit to a predetermined location of the modulated codeword. Since the DSV control bit pattern is inserted between modulated codewords, the RLL rule, the basic rule of modulation code, should be satisfied by the DSV control bit pattern. When a dataword is modulated to a codeword using the Jacoby code table of FIG. 2, the DSV control bit patterns are inserted at any one of a location between the MSB and the LSB of modulated codeword, a location after the LSB of the codeword in the substitution table 220, and a location before the MSB of the codeword in the substitution table 220.

Bit values of the DSV control bit patterns are only examples. The bit values may vary according to a type of the modulation code table. However, although the dataword is modulated according to any code table, the RLL (d, k) rule should be satisfied. In the above embodiment, d and k may be respectively 1 and 7.

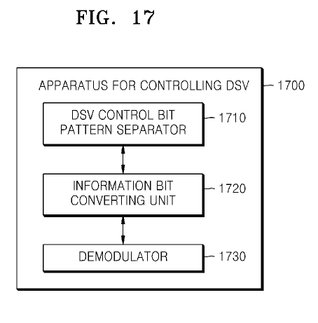

FIG. 17 shows an apparatus 1700 to control the DSV, according to another embodiment of the present invention. The apparatus 1700 includes a DSV control bit pattern separating unit 1710, an information bit converting unit 1720, and a demodulator 1730. The DSV control bit pattern separating unit 1710 separates a plurality of the DSV control bit patterns inserted into a modulated codeword and a codeword which indicates predetermined information represented by at least one bit.

The information bit converting unit 1720 converts the DSV control bit patterns separated by the DSV control bit pattern separating unit 1710 into at least one bit which represents predetermined information. If the separated DSV control bit patterns correspond to at least one of ‘000001’, ‘000101’, ‘100000’, ‘100100’, ‘001000,’ and ‘001010,’ the separated DSV control bit patterns are decoded to information bit ‘0.’ If the separated DSV control bit patterns correspond to at least one of ‘010101’, ‘010001’, ‘101010’, ‘101000’, ‘010000,’ and ‘010100,’ the separated DSV control bit patterns are decoded to information bit ‘1.’

The demodulator 1730 demodulates the codeword separated by the DSV control bit pattern separating unit 1710 to dataword according to a predetermined demodulation code table. Demodulation progresses in a reverse order of the modulation performed by the modulator 1610 in FIG. 16 in which a dataword is modulated to a codeword.

The DSV control bit is a redundancy bit which conventionally does not have specific information and thus is discarded after the demodulation is completed. However, according to aspects of the present invention, the plurality of the DSV control bit patterns indicate predetermined information represented by at least one bit so that the DSV control bit patterns control the DSV and can be used as predetermined information, instead of being discarded after the demodulation is completed. Therefore, an information storage medium can be efficiently used in DSV control capable of storing information bit.

Aspects of the present invention can also be embodied as computer readable codes on a computer readable recording medium. The computer readable recording medium is any data storage device that can store data which can be thereafter read by a computer system. Examples of the computer readable recording medium include read-only-memory (ROM), random-access memory (RAM), CDs, DVDs, magnetic tapes, floppy disks, and optical storage devices. The computer readable recording medium can also be distributed over network coupled computer system so that the computer readable code is stored and executed in a distributed fashion. Also, functional programs, codes, and code segments for accomplishing the present invention can be easily construed by programmers skilled in the art to which the present invention pertains.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of controlling a Digital Sum Value (DSV), comprising:
generating a plurality of DSV control bit patterns indicating predetermined information represented by at least one bit;
inserting any one of the generated DSV control bit patterns at a predetermined location of a modulated codeword; and
recording the modulated codeword having the inserted DSV control bit pattern onto a computer-readable medium.

2. The method of claim 1, further comprising modulating an input dataword to a codeword according to a predetermined modulation code table.

3. The method of claim 1, wherein the plurality of the DSV control bit patterns is generated to satisfy a RLL (d, k) rule, wherein d and k are respectively the minimum length and the maximum length of consecutive O's into which a codeword to which the one DSV control bit pattern is inserted.

4. The method of claim 3, wherein d is 1 and k is 7.

5. The method of claim 3, wherein the plurality of the DSV control bit patterns have parities opposite to each other.

6. The method of claim 3, wherein the plurality of the DSV control bit patterns have opposite Codeword Sum Values (CSVs) having opposite signs, the CSV indicating the DSV of one codeword.

7. The method of claim 3, wherein the plurality of the DSV control bit patterns have parities opposite to each other and CSVs having opposite signs.

8. The method of claim 1, wherein the inserting of any one of the generated DSV control bit patterns at a predetermined location of the modulated codeword comprises inserting the DSV control bit pattern at one of a location between the most significant bit (MSB) and the least significant bit (LSB) of the modulated codeword, a location after the LSB of the codeword, and a location before the MSB of codeword.

9. The method of claim 1, wherein the predetermined information comprises any one of address information to rapidly and randomly access data and determine a data recorded location; padding information indicating that unavailable data is contained while recording data; information indicating whether data type is real-time data; information indicating whether data is provided by a host; disk management information; information indicating data generated by a drive; copy protection information for encryption; and information indicating an encryption key.

10. A computer readable recording medium having embodied thereon a computer program to execute the method of claim 1.

11. A method of controlling a Digital Sum Value (DSV), comprising:
separating a plurality of the DSV control bit patterns inserted into a modulated codeword and a codeword, wherein the plurality of the DSV control bit patterns indicates predetermined information represented by at least one bit; and
converting the separated DSV control bit patterns into at least one bit which represents the predetermined information; and
reproducing data contained in the codeword based on the predetermined information.

12. The method of claim 11, further comprising:
demodulating the separated codeword to a dataword according to a predetermined demodulation table.

13. An apparatus to control a Digital Sum Value (DSV), comprising:
a DSV control bit pattern generating unit to generate a plurality of the DSV control bit patterns indicating predetermined information represented by at least one bit; and
a DSV control bit pattern inserting unit to insert one of the generated DSV control bit patterns into a modulated codeword.

14. The apparatus of claim 13, further comprising a modulator to modulate input data to a codeword according to a predetermined modulation code table.

15. The apparatus of claim 13, wherein the DSV control bit pattern generating unit generates the plurality of the DSV control bit patterns to satisfy a RLL (d, k) rule, wherein d and k are respectively the minimum length and the maximum length of consecutive 0's in which a codeword to which the one DSV control bit pattern is inserted.

16. The apparatus of claim 15, wherein d is 1 and k is 7.

17. The apparatus of claim 15, wherein the plurality of the DSV control bit patterns have parities opposite to each other.

18. The apparatus of claim 15, wherein the plurality of the DSV control bit patterns have Codeword Sum Values (CSVs) having opposite signs, the CSV indicating the DSV of one codeword.

19. The apparatus of claim 15, wherein the plurality of the DSV control bit patterns have parities opposite to each other and CSVs having opposite signs.

20. The apparatus of claim 15, wherein the DSV control bit pattern inserting unit inserts the DSV control bit pattern at one of a location between the most significant bit (MSB) and the least significant bit (LSB) of the modulated codeword, a location after the LSB of the codeword, and a location before the MSB of the codeword.

21. The apparatus of claim 13, wherein the predetermined information comprises any one of address information to rapidly and randomly access data and determine a data recorded location; padding information indicating that unavailable data is contained while recording data; information indicating whether a data type is real-time data; information indicating whether data is provided by a host; disk management information; information indicating data generated by a drive; copy protection information for encryption; and information indicating an encryption key.

22. An apparatus to control a Digital Sum Value (DSV), comprising:
a DSV control bit pattern separating unit to separate a plurality of DSV control bit patterns inserted into a modulated codeword and a codeword, wherein the plurality of DSV control bit patterns indicates predetermined information represented by at least one bit; and
an information bit converting unit to convert the separated DSV control bit patterns into at least one bit that represents the predetermined information.

23. The apparatus of claim 22, further comprising a demodulator to demodulate the separated codeword to a dataword according to a predetermined demodulation table.
